(19) United States
(12) Patent Application Publication
(10) Pub. No.: US 2018/0247903 A1
(43) Pub. Date: Aug. 30, 2018

(54) SEMICONDUCTOR DEVICE AND METHOD OF MANUFACTURING A SEMICONDUCTOR DEVICE

(71) Applicant: SII Semiconductor Corporation, Chiba-shi (CN)

(72) Inventor: Tetsuya SAKUMA, Chiba-shi, Chiba (JP)

(21) Appl. No.: 15/845,189

(22) Filed: Dec. 18, 2017

(30) Foreign Application Priority Data
Feb. 24, 2017 (JP) 2017-033328

(51) Int. Cl. H01L 23/62; H01L 21/822; H01L 27/04; H01L 23/525

(52) U.S. Cl. CPC H01L 23/62; H01L 23/525; H01L 27/04; H01L 21/822

(57) ABSTRACT

Provided are a semiconductor device in which a fuse element can be stably fused without generating a crack in a base insulating film even when a protective insulating film on the fuse element, which is to be subjected to laser trimming, is thick, and a method of manufacturing the semiconductor device. The fuse element including a laser irradiation portion has chamfers obtained by chamfering corner portions between side surfaces and a bottom surface of the laser irradiation portion.

### RELATED APPLICATIONS

This application claims priority under 35 U.S.C. § 119 to Japanese Patent Application No. 2017-033328 filed on Feb. 24, 2017, the entire content of which is hereby incorporated by reference.

### BACKGROUND OF THE INVENTION

### 1. Field of the Invention

The present invention relates to a semiconductor device and a method of manufacturing a semiconductor device, and more particularly, to a semiconductor device including a fuse element to be fused by laser irradiation and a method of manufacturing a semiconductor device.

### 2. Description of the Related Art

There is known a method of adjusting a resistance value, or a method of performing trimming adjustment of a redundant circuit in a semiconductor device by irradiating with a laser a fuse element made of, for example, polysilicon, metal, or high-melting point metal, so as to fuse the fuse element.

FIG. 8A is a plan view of a related-art fuse element, and FIG. 8B is a cross-sectional view taken along the line A-A′ of FIG. 8A. For example, as illustrated in FIG. 8A, a fuse element 53 includes a laser irradiation portion 63 and contact portions 64 including contact regions 61, which are formed at both ends of the laser irradiation portion 63. The fuse element 53 is made of a conductive material, for example, polysilicon or metal. As illustrated in FIG. 8B, the fuse element 53 is formed on a base insulating film 52, which is, for example, a silicon oxide film, and is formed on a semiconductor substrate 51. On the fuse element 53, a protective insulating film 54 being, for example, a silicon oxide film, is formed. To fuse the fuse element 53, a laser L is radiated from above the fuse element 53 as illustrated in FIG. 8B. In this way, the laser irradiation portion 63 of the fuse element 53 is heated to melt and evaporate, thereby being caused to explosively scatter.

In Japanese Patent Application Laid-open No. Sho 60-91654, there is proposed a technology enabling a fuse element to be fused by a laser having low energy in order to suppress a crack of a lower substrate, which is caused by a laser having increased energy.

However, the inventor of the present invention has found out that a crack is more liable to occur in a base insulating film as a semiconductor device is more highly integrated, that is, the number of laminated layers of metal wiring lines and the number of layers of inter-layer insulating films each increase and the thickness of a protective insulating film increases.

As illustrated in FIG. 9, when a protective insulating film 74 is thin, after a fuse element is fused, the protective insulating film 74 radially disappears upward in its cross section. FIG. 10 is a view of a semiconductor device after a fuse element is fused in a case in which a protective insulating film is thick. When a protective insulating film 84 is thick, as illustrated in FIG. 10, energy of melting and evaporating the fuse element affects a base insulating film 82 under the fuse element, thereby causing cracks 86 in two obliquely downward directions.

Further, it has been found that it is difficult to stably fuse a fuse element when a difference between a lower limit value and an upper limit value of desired energy of a laser becomes extremely small and the protective insulating film 84 has a thickness that is twice or more of that of the base insulating film 82.

As the protective insulating film 84 becomes thicker, a laser needs to have higher energy. The reason for the fact is inferred to be that breaking strength of the protective insulating film 84 is increased and the protective insulating film 84 cannot be caused to scatter unless a laser having increased energy is radiated in accordance with the increased breaking strength of the protective insulating film 84. Further, the following may be considered to be the reason why the cracks 86 are more liable to occur in the base insulating film 82 when the protective insulating film 84 becomes thicker. Specifically, when the breaking strength of the protective insulating film 84 is increased, the protective insulating film 84 scatters less easily at the time when the fuse element melts and evaporates. As a result, the ratio of stress applied to corner portions in the two obliquely downward directions increases.

### SUMMARY OF THE INVENTION

In view of the above, the present invention has an object to provide a semiconductor device in which a crack in a base insulating film is prevented from occurring and a fuse element can be stably fused, and a method of manufacturing the semiconductor device.

According to one embodiment of the present invention, there are provided a semiconductor device and a method of manufacturing the semiconductor device that are described below.

That is, the semiconductor device includes: a base insulating film; a fuse element formed on the base insulating film, and including a laser irradiation portion having a lengthwise direction and a widthwise direction; and a protective insulating film for covering the fuse element, in which the laser irradiation portion has, in the lengthwise direction, chamfers between a bottom surface of the laser irradiation portion and a first side surface of the laser irradiation portion and between the bottom surface and a second side surface of the laser irradiation portion, the bottom surface being in contact with the base insulating film, the first side surface being located at one end of the laser irradiation portion in the widthwise direction, the second side surface being located at another end of the laser irradiation portion in the widthwise direction.

Further, the method of manufacturing a semiconductor device includes: forming a base insulating film on a semiconductor substrate; forming a fuse layer on the base insulating film; forming, after depositing an insulating layer on the fuse layer, an insulating layer mask on a region of the insulating layer in which a fuse element is to be formed; forming the fuse element, in which a corner portion between a bottom surface of the fuse element and a side surface of the fuse element is chamfered, by dry etching the fuse layer with use of the insulating layer mask as an etching mask; and forming a protective insulating film on the fuse element.

According to one embodiment of the present invention, the fuse element has the chamfers formed by chamfering the corner portions between the side surfaces and the bottom surface of the laser irradiation portion. With this configuration, it is possible to relax concentration of stress applied obliquely downward at the time when the fuse element is caused to melt and evaporate even when irradiation energy of a laser is increased in accordance with a thickness of the protective insulating film. Accordingly, the semiconductor device in which cracks are prevented from occurring in the base insulating film and the fuse element can be stably fused can be achieved.

### BRIEF DESCRIPTION OF THE DRAWINGS

FIG. 1A is a plan view of a semiconductor device according to a first embodiment of the present invention, and FIG. 1B is a cross-sectional view of the semiconductor device illustrated in FIG. 1A.

FIG. 2A, FIG. 2B, and FIG. 2C are step flow diagrams for illustrating a method of manufacturing the semiconductor device illustrated in FIG. 1A and FIG. 1B.

FIG. 3 is a cross-sectional view of a semiconductor device according to a second embodiment of the present invention.

FIG. 4A, FIG. 4B, FIG. 4C, and FIG. 4D are step flow diagrams for illustrating a method of manufacturing the semiconductor device illustrated in FIG. 3.

FIG. 5 is a cross-sectional view of a semiconductor device according to a third embodiment of the present invention.

FIG. 6A, FIG. 6B, and FIG. 6C are step flow diagrams for illustrating a method of manufacturing the semiconductor device illustrated in FIG. 5.

FIG. 7 is a cross-sectional view of a semiconductor device according to a fourth embodiment of the present invention.

FIG. 8A is a plan view of a related-art semiconductor device, and FIG. 8B is a cross-sectional view of the semiconductor device illustrated in FIG. 8A.

FIG. 9 is a cross-sectional view after a fuse element of a semiconductor device including a thin protective insulating film is fused.

FIG. 10 is a cross-sectional view for illustrating how cracks occur in a base insulating film at the time when a fuse element of a semiconductor device including a thick protective insulating film is fused.

### DETAILED DESCRIPTION OF THE PREFERRED EMBODIMENTS

Now, embodiments of the present invention are described with reference to the drawings.

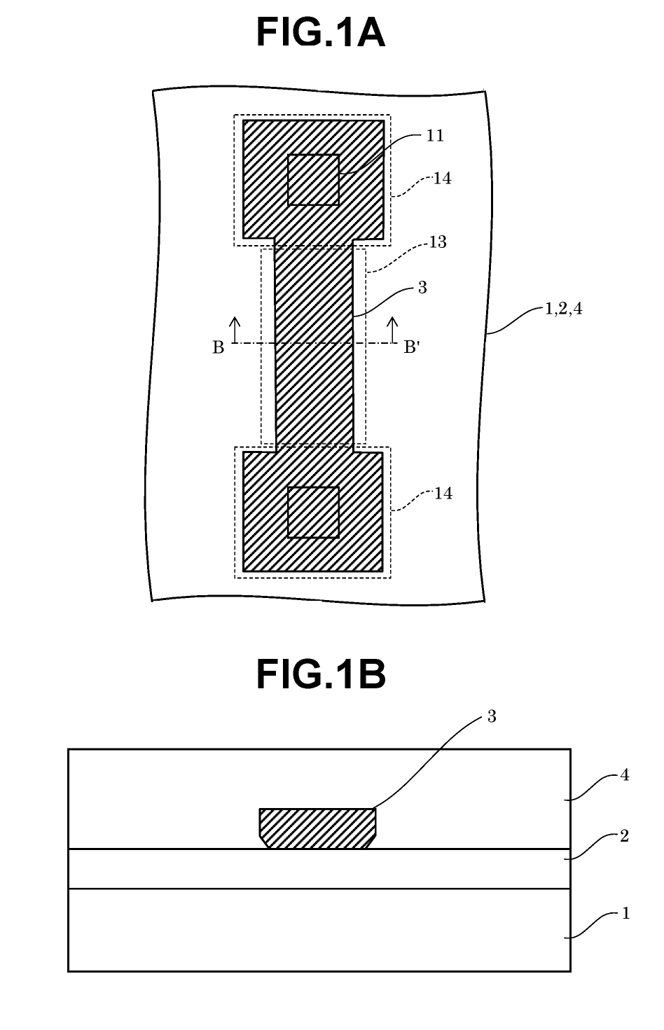

FIG. 1A is a plan view of a fuse element of a first embodiment of the present invention, and FIG. 1B is a cross-sectional view taken along the line B-B′ of FIG. 1A.

As illustrated in FIG. 1A, a fuse element 3 includes a laser irradiation portion 13 having a small width, which can be easily fused by a laser, and contact portions 14 each having a large width, which are formed at both ends of the laser irradiation portion 13 in a lengthwise direction of the laser irradiation portion 13.

The laser irradiation portion 13 is made of a conductive material which can be cut by irradiation with a laser, for example, polysilicon, high-melting point metal, such as titanium and cobalt, or metal, such as aluminum and copper. In FIG. 1A, a length along the lengthwise direction, which is the vertical direction, of the laser irradiation portion 13 is illustrated longer than a width along the widthwise direction, which is the horizontal direction, of the laser irradiation portion 13, but the dimensional relationship is not limited thereto. Further, in FIG. 1A, both right and left side surfaces present in a widthwise direction of the laser irradiation portion 13 are perpendicular to the surface of the semiconductor substrate, but the angle is not limited to be perpendicular. In the present invention, a surface present between one end of the laser irradiation portion 13 and the other end thereof along the lengthwise direction is referred to as “side surface”.

The contact portions 14 are portions including contact regions 11 in contact with a metal wiring line (not shown), and are made of a conductive material, for example, polysilicon, high-melting point metal, or metal. However, the material of the contact portions 14 does not need to be the same as that of the laser irradiation portion 13. For example, there may be employed a configuration in which the laser irradiation portion 13 is made of polysilicon while the contact portions 14 are formed of silicide layers obtained by silicidation of the polysilicon with high-melting point metal.

Further, as illustrated in FIG. 1B, the fuse element 3 is formed on a base insulating film 2, which is, for example, a silicon oxide film, and is formed on a semiconductor substrate 1.

As the base insulating film 2, a LOCOS insulating film or an STI insulating film for element isolation is used when the fuse element 3 is made of polysilicon. Further, when the fuse element 3 is made of metal, a BPSG film and an inter-layer insulating film for isolation between wiring lines are further laminated. However, the configuration of the base insulating film 2 is not limited to the films made of those materials as long as the base insulating film 2 serves as an insulating film.

On the fuse element 3, a protective insulating film 4, which is a silicon oxide film or a silicon nitride film, is formed. The protective insulating film 4 is formed in order to avoid damage to or deterioration of the fuse element 3 due to a direct contact of the fuse element 3 with moisture or a foreign substance. In order to fulfill its role, the protective insulating film 4 is formed of any one of a BPSG film, an inter-layer insulating film, and a passivation film, or a combination thereof. The protective insulating film 4 is not particularly limited to those described above as long as the protective insulating film 4 serves as an insulating film.

As illustrated in FIG. 1B, a cross section of the laser irradiation portion 13 of the fuse element 3 of the first embodiment has chamfers formed by chamfering a first corner portion between a bottom surface of the fuse element 3 and the right side surface and a second corner portion between the bottom surface and the left side surface. Each of the chamfers is formed along the side surface located at one end in the widthwise direction of the laser irradiation portion 13, and the respective chamfers are formed on the right and left side of the laser irradiation portion 13.

In the first embodiment, the bottom surface and top surface of the laser irradiation portion 13 are parallel to each other, which is similar to the related art.

By the way, the inventor of the present invention has observed the following phenomenon. Specifically, when the protective insulating film 4 has a thickness that is 2.5 times or more of that of the base insulating film 2, a fusing failure of the fuse element 3 is liable to occur. Accordingly, while energy of a laser needs to be increased, in this case, cracks are liable to occur in the base insulating film 2. The inventor of the present invention considers the following as the reason for the occurrence of that phenomenon.

When the laser irradiation portion 13 melts and evaporates by laser irradiation and explodes due to increased vapor pressure, protruded corner portions of the laser irradiation portion 13 are extruded to the outside due to an expansion action at the time when the laser irradiation portion 13 melts and evaporates. Then, stress is concentrated to recessed portions of the insulating film, which are in contact with the protruded corner portions. Accordingly, at the time when the insulating films at the corner portions in four oblique directions in the cross section of the laser irradiation portion 13 are radially extruded, if the protective insulating film 4 is thin, the protective insulating film 4 breaks to scatter along two obliquely upward directions of the protective insulating film 4 having low breaking strength. On the other hand, when the protective insulating film 4 on the laser irradiation portion 13 is thick and hard and the protective insulating film 4 in contact with the corner portions in the two obliquely upward directions of the laser irradiation portion 13 thus breaks less easily, stress is concentrated to the base insulating film 2 in contact with the corner portions in two obliquely downward directions of the laser irradiation portion 13 on its bottom surface side. When the stress exceeds breaking strength of the base insulating film 2, cracks occur in the two obliquely downward directions.

In other words, when the protective insulating film 4 becomes thicker, a permissible lower limit of energy of the laser rises in order to cause the protective insulating film 4 to scatter simultaneously with the melting and evaporating of the fuse element 3, and a permissible upper limit of energy of the laser lowers in order to avoid cracks in the base insulating film 2. As a result, it becomes difficult to stably fuse the fuse element 3.

In the first embodiment, the chamfers are formed by chamfering the corner portions in the two obliquely downward directions along the lengthwise direction of the laser irradiation portion 13 as illustrated in FIG. 1B to disperse the stress concentration in the two obliquely downward directions within those chamfers, to thereby prevent cracks from occurring in the base insulating film 2. Further, in accordance with that, the stress generated by melting and evaporating the fuse element 3 is concentrated at the right-angled corner portions in the two obliquely upward directions of the fuse element 3, to thereby cause the protective insulating film 4 covering the laser irradiation portion 13 to effectively scatter.

In the first embodiment, the protective insulating film 4 in contact with the corner portions in the two obliquely upward directions of the laser irradiation portion 13 easily breaks at the time when the laser irradiation portion 13 melts and evaporates. Thus, cracks in the base insulating film 2 can be prevented from occurring in a case in which the protective insulating film 4 is thick. Accordingly, it is possible to provide the semiconductor device in which the fuse element 3 can be stably fused even when the protective insulating film 4 is thick due to multi-layering of metal wiring lines.

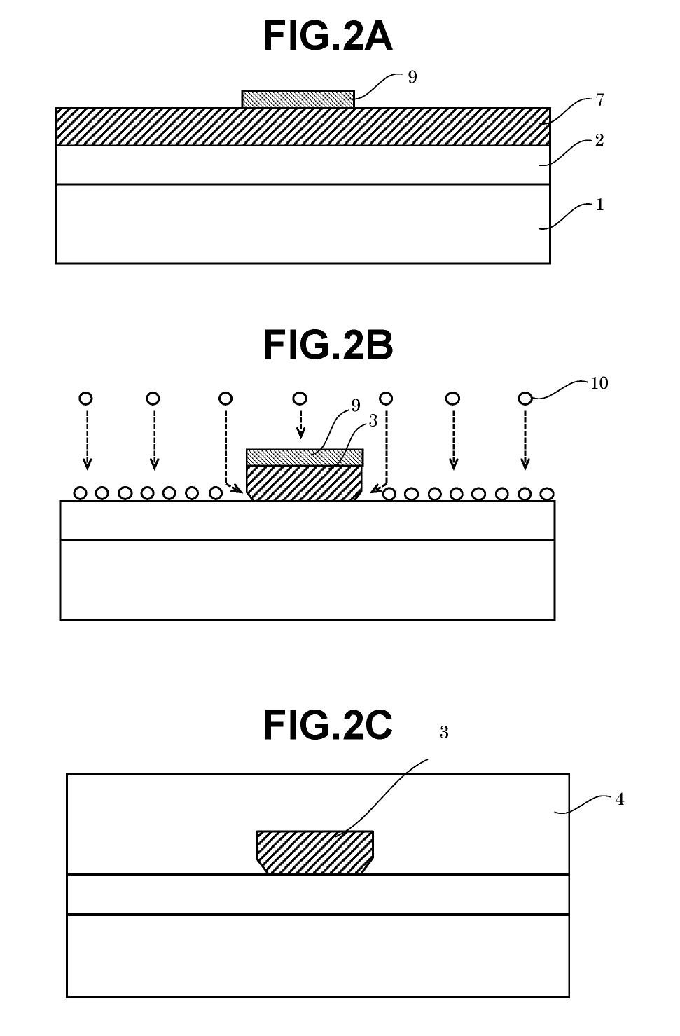

Next, a method of manufacturing the semiconductor device according to the first embodiment is described with reference to FIG. 2A to FIG. 2C.

First, as illustrated in FIG. 2A, the base insulating film 2 being, for example, a silicon oxide film, is formed on the semiconductor substrate 1. A LOCOS insulating film or an STI insulating film may also be used as the base insulating film 2. Then, a fuse layer 7 made of, for example, polysilicon, is formed on the base insulating film 2.

Next, a photoresist 9 is applied onto the fuse layer 7, and is processed into an insulating layer mask having a shape of the fuse element 3 with the use of a photolithography technology.

Then, as illustrated in FIG. 2B, the fuse layer 7 except for the region on which the photoresist 9 is present is removed by etching with the use of reactive ion etching (RIE) method while using the photoresist 9 as a mask, to thereby pattern the fuse layer 7 into the shape of the fuse element 3. At this time, an over-etching amount of the fuse layer 7 is adjusted, and etching is performed such that the fuse element 3 is smaller in width than the photoresist 9 at the two corner portions between the bottom surface and the side surfaces of the resultant fuse element 3, thereby performing chamfering.

In general, it is known that, in dry etching with the use of the RIE method, a narrow portion called “notch” is generated at a lower part of a material to be etched when over etching is excessively performed after removing the material to be etched on an insulator and exposing the underlain insulator. It is considered that this phenomenon occurs because, in the over etching, ions in etching species stagnate on the insulator under the material to be etched, and a track of ions radiated later is bent, with the result that etching proceeds to side walls at the lower part of the material which receives the etching.

The first embodiment utilizes this phenomenon, and the corner portions at the lower part of the side surfaces of the fuse element 3 are chamfered by generating notches in the fuse element 3 with the use of positive ions 10 generated during etching.

Then, as illustrated in FIG. 2C, the protective insulating film 4 is deposited on the fuse element 3 with the use of a CVD method, for example. After a step of forming a metal wiring line, which is not shown, is performed, the semiconductor device according to the first embodiment is finished.

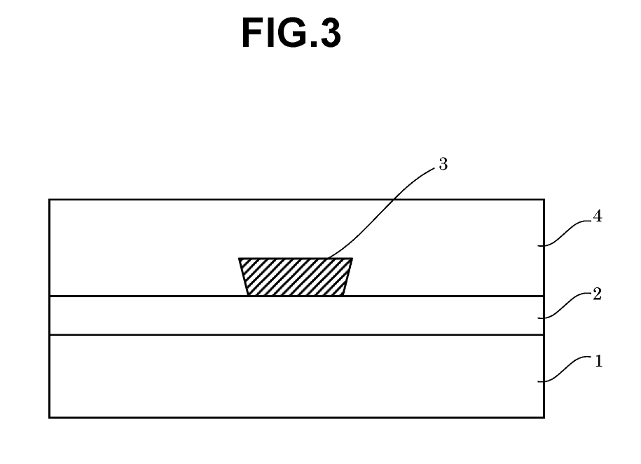

Next, a second embodiment of the present invention is described. FIG. 3 is a cross-sectional view of a semiconductor device according to the second embodiment. A planer shape thereof is the same as that of the semiconductor device according to the first embodiment, which is illustrated in FIG. 1A.

In FIG. 3, the base insulating film 2 is formed on the semiconductor substrate 1, and the fuse element 3 made of a conductive material, for example, polysilicon, is formed on the base insulating film 2. Further, the protective insulating film 4 is formed on the fuse element 3. The fuse element 3 of the second embodiment has a reversely tapered cross section of a trapezoid obtained by connecting each of two slopes, which are formed by chamfering, to a top surface of the fuse element 3.

Similarly to the first embodiment, the stress applied to the corner portions in the two obliquely downward directions on the bottom surface side of the fuse element 3 is relaxed at the time when the laser irradiation portion 13 of the fuse element 3 having the configuration described above melts and evaporates to increase the vapor pressure and explode. In the second embodiment, the corner portions in the two obliquely upward directions on a top surface side of the fuse element 3 are each formed into an acute angle of less than 90 degrees. Thus, at the time when the fuse element 3 melts and evaporates by laser irradiation, the stress is more concentrated at those corner portions in the two obliquely upward directions than in the first embodiment, thereby increasing a breaking effect of the protective insulating film 4 on the top surface. Accordingly, the semiconductor device according to the second embodiment has an advantage of having a higher effect of preventing cracks from occurring in the base insulating film 2 than that of the first embodiment.

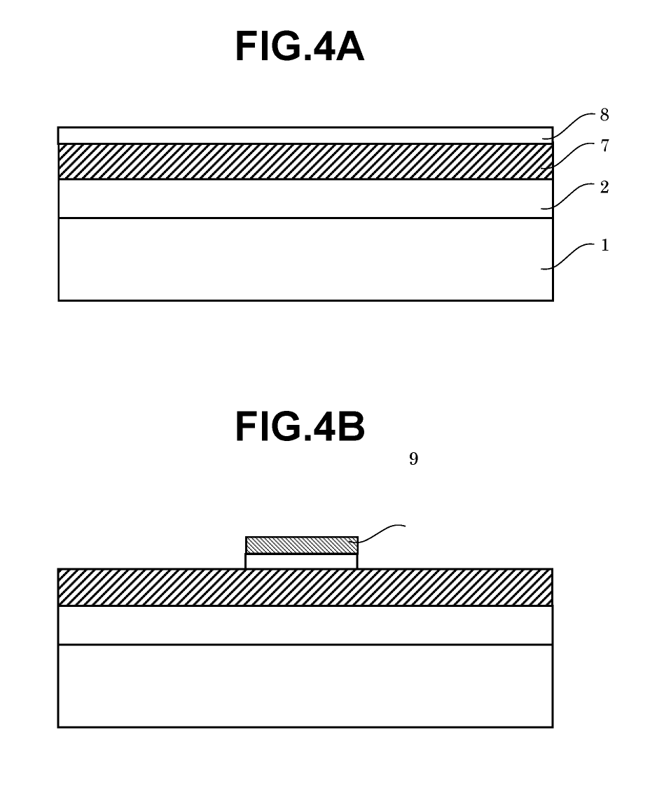

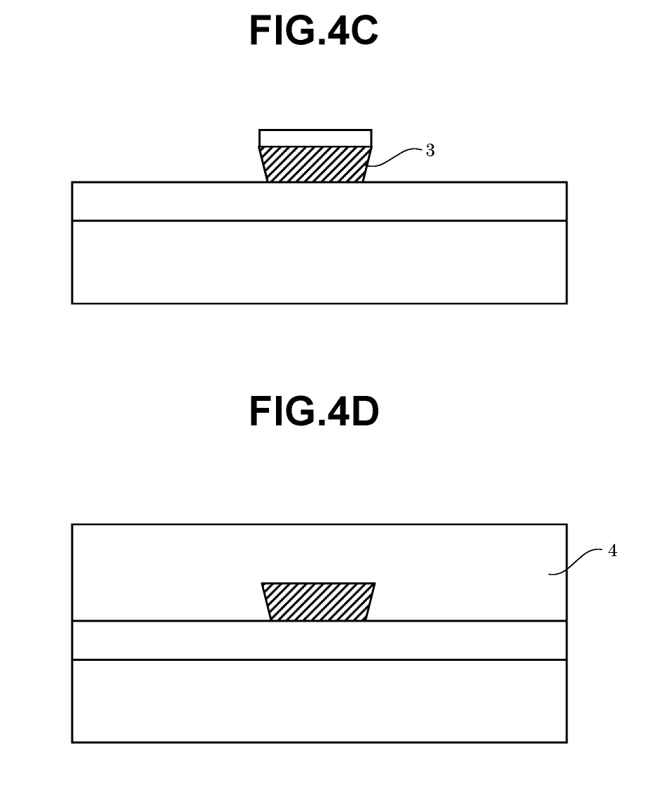

Next, a method of manufacturing the semiconductor device according to the second embodiment is described with reference to FIG. 4A to FIG. 4D.

First, as illustrated in FIG. 4A, the base insulating film 2 being, for example, a silicon oxide film, is formed on the semiconductor substrate 1, and the fuse layer 7 made of, for example, polysilicon, is formed on the base insulating film 2. Then, a mask insulating film 8 being, for example, a silicon oxide film, is deposited on the fuse layer 7.

Next, as illustrated in FIG. 4B, the photoresist 9 is applied onto the mask insulating film 8, and is processed into a shape of the fuse element 3 with the use of the photolithography technology. Then, the mask insulating film 8 except for the region on which the photoresist 9 is present is removed by etching while using the photoresist 9 as a mask.

Further, after the photoresist 9 is removed, as illustrated in FIG. 4C, the fuse layer 7 except for the region on which the mask insulating film 8 is present is removed by etching with the use of the RIE method while using the mask insulating film 8 as a mask, to thereby form the fuse element 3.

In general, in dry etching with the use of the RIE method, both processes of etching and deposition of secondary product generated during etching simultaneously occur. The process of etching dominantly progresses on a surface of the material to be etched, while the process of the deposition of secondary product progresses more dominantly than etching on side walls of the material to be etched due to less irradiation of ions. Thus, the secondary product serves as protection of the side walls, and etching in the vertical direction progresses more than that in the horizontal direction. As a result, an anisotropic shape of the material to be etched tends to be achieved.

One factor contributing to the secondary product protecting the material to be etched from etching in the horizontal direction may be the material of the etching mask. In the second embodiment, the etching mask is changed from a photoresist which tends to generate a carbon-based secondary product to the insulating film being, for example, the silicon oxide film, thereby reducing the effect of the protection of side walls. Thus, etching gradually progresses under the mask insulating film 8 in the direction of the side surfaces of the fuse element 3. As a result, the final cross section of the fuse element 3 has a shape of a reversely tapered trapezoid.

Then, as illustrated in FIG. 4D, the protective insulating film 4 is formed on the fuse element 3 with the use of the CVD method, for example. After a step of forming a metal wiring line, which is not shown, is performed, the semiconductor device according to the second embodiment is finished.

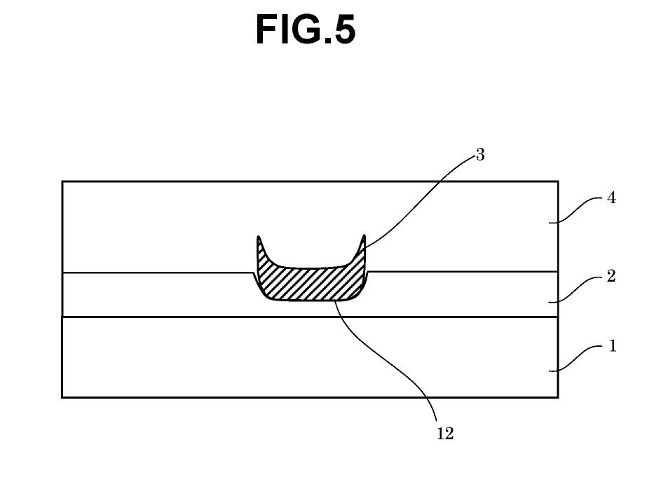

Next, a third embodiment of the present invention is described. FIG. 5 is a cross-sectional view of a semiconductor device according to the third embodiment. Although not shown, a planer shape thereof is the same as that of the semiconductor device according to the first embodiment, which is illustrated in FIG. 1A.

In FIG. 5, the base insulating film 2 is formed on the semiconductor substrate 1, and an insulating film recessed portion 12 is formed on the surface of the base insulating film 2. On the insulating film recessed portion 12, the fuse element 3 made of a conductive material, for example, polysilicon, is formed. The laser irradiation portion 13 of the fuse element 3 has a bottom surface in which both ends thereof are rounded in accordance with the shape of the insulating film recessed portion 12, and has chamfers having a rounded surface protruding toward the outside. In accordance with that shape, both ends of the top surface of the laser irradiation portion 13 are rounded, and as a result, the top surface of the laser irradiation portion 13 includes the insulating film recessed portion 12 having a bottom part, which is parallel to the bottom surface of the laser irradiation portion 13. Further, the protective insulating film 4 is deposited on the fuse element 3.

The laser irradiation portion 13 of the fuse element 3 of the third embodiment has the rounded corner portions of the side surfaces located at one short part in the widthwise direction on the bottom surface side. Accordingly, the stress concentration to the corner portions in the two obliquely downward directions can be relaxed at the time when the laser irradiation portion 13 of the fuse element 3 of the third embodiment is irradiated with a laser to melt and evaporate. Further, in the third embodiment, the corner portions of both ends of the top surface of the laser irradiation portion 13 are each formed into an acute angle of less than 90 degrees and are acuter than the corner portions in the two obliquely upward directions on the top surface side of the fuse element 3 of the second embodiment. Thus, at the time when the fuse element 3 melts and evaporates by laser irradiation, stress is more concentrated at the corner portions in the two obliquely upward directions than in the second embodiment, thereby facilitating breakdown of the protective insulating film 4 on the top surface. Accordingly, the semiconductor device according to the third embodiment can achieve a higher effect of preventing cracks from occurring in the base insulating film 2 than that of the first embodiment.

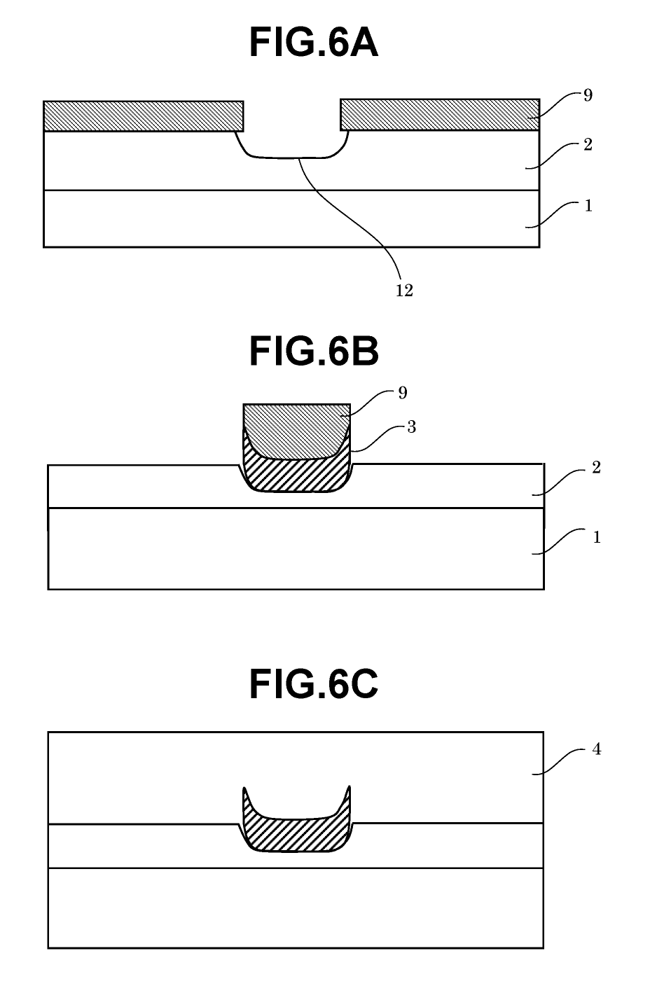

Next, a method of manufacturing the semiconductor device according to the third embodiment is described with reference to FIG. 6A to FIG. 6C.

First, as illustrated in FIG. 6A, the base insulating film 2 being, for example, a silicon oxide film, is formed on the semiconductor substrate 1. Under that state, the photoresist 9 is applied to the resultant, and a region of the photoresist 9 in which the fuse element 3 is to be formed is opened. The shape of this opening is formed by a photomask which is made with the use of data obtained by inverting white and black of a pattern of the fuse element 3. Then, with the use of the photoresist 9 as a mask, the base insulating film 2 is recessed by isotropic etching, for example, wet etching, to form the insulating film recessed portion 12. At this time, a pattern wider than the opening width of the photoresist 9 is formed by isotropic etching.

Next, as illustrated in FIG. 6B, after the photoresist 9 is removed, the fuse layer 7 made of, for example, polysilicon, is formed, and the photoresist 9 is applied to be patterned into the shape of the fuse element 3. Finally, the fuse layer 7 is etched with use of the photoresist 9 as a mask, to thereby form the fuse element 3.

The fuse element 3 obtained by adopting those steps is formed inside the insulating film recessed portion 12 of the base insulating film 2, which is formed by isotropic etching. In addition, the corner portions in the two obliquely downward directions on the bottom surface side of the fuse element 3 are rounded along inner walls of the insulating film recessed portion 12, while the corner portions in the two obliquely upward directions on the top surface side of the fuse element 3 are formed into the acute angles.

Then, as illustrated in FIG. 6C, the protective insulating film 4 is formed on the fuse element 3 with the use of the CVD method, for example. After performing a step of forming a metal wiring line, which is not illustrated, the semiconductor device is finished.

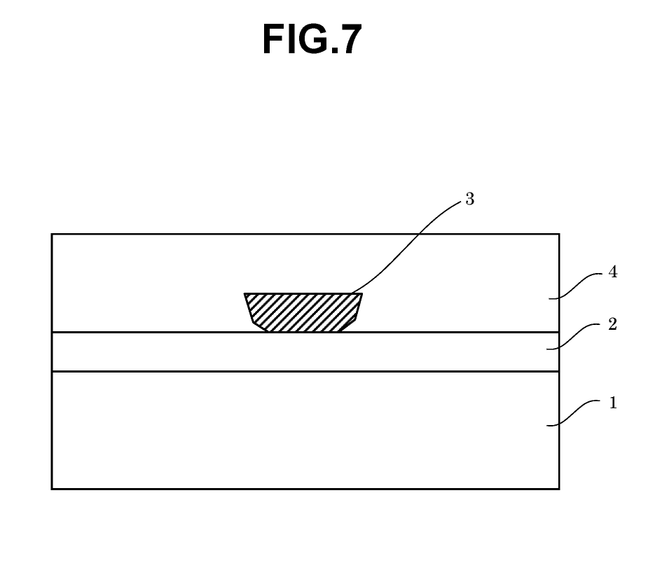

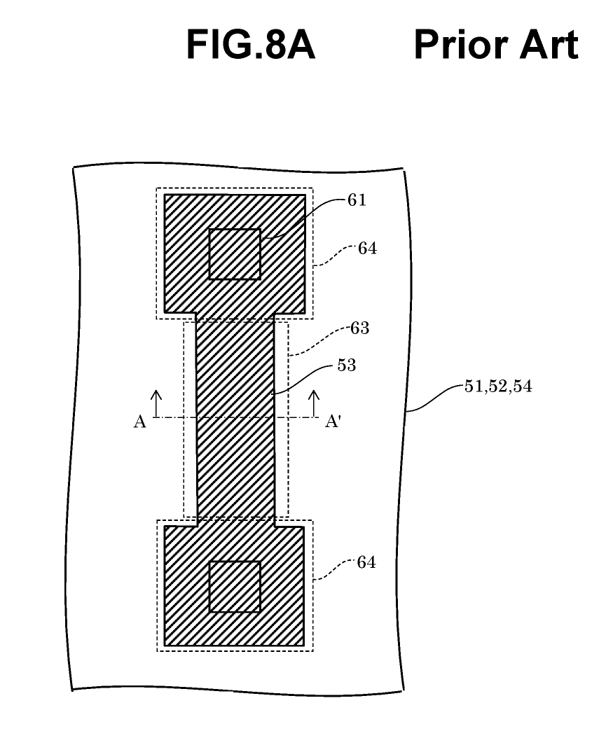

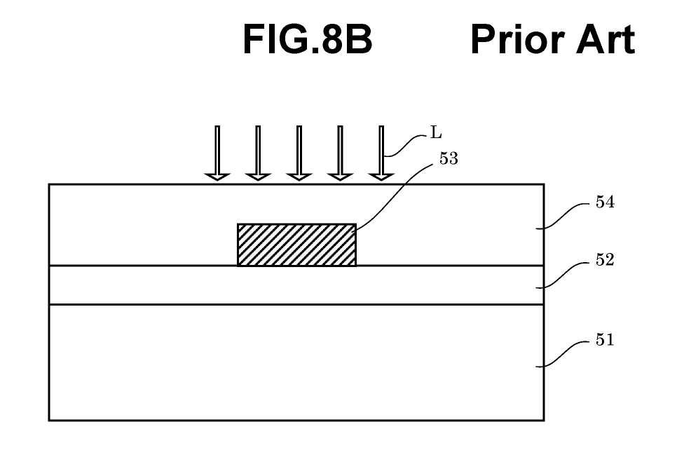

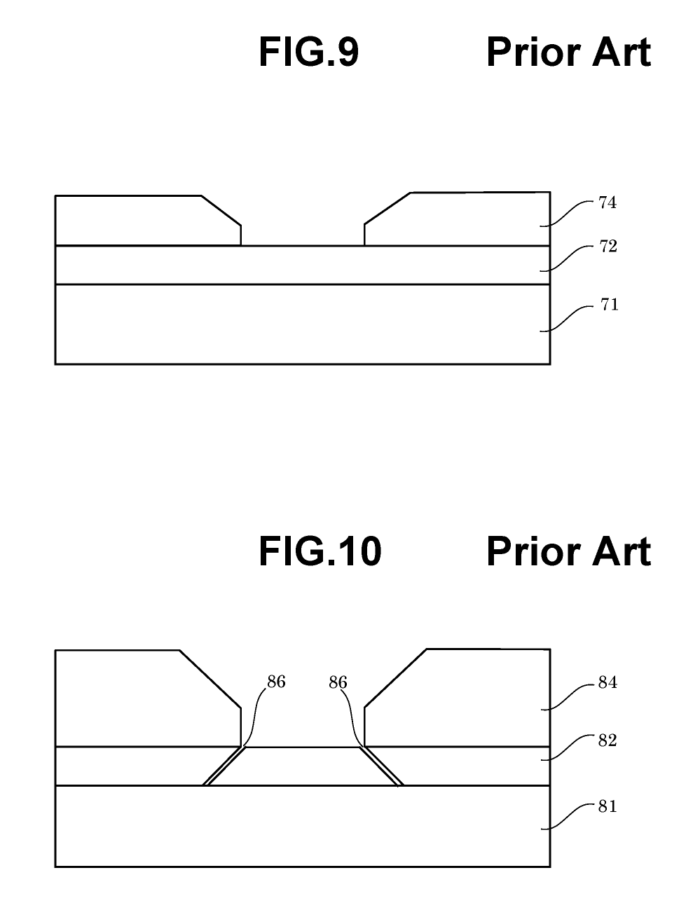

Each of the embodiments of the present invention described above may also be used in combination thereof in various ways. For example, a fourth embodiment of the present invention obtained by combining the first embodiment and the second embodiment is illustrated in FIG. 7. In FIG. 7, the fuse element 3 has the side walls of the laser irradiation portion 13, which are formed into a tapered shape, and chamfers obtained by chamfering the corner portions in the two obliquely downward directions of the side walls. With this configuration, the stress, which is generated at the time when the laser irradiation portion 13 melts and evaporates by laser irradiation and is applied to the corner portions in the two obliquely downward directions of the fuse element 3, can be relaxed at a level equivalent to that of the first embodiment, while the stress applied to the corner portions in the two obliquely upward directions can be concentrated at a level equivalent to that of the second embodiment. As a result, the protective insulating film 4 covering the laser irradiation portion 13 can be caused to effectively scatter.

Further, the configuration described above can be obtained by adopting a manufacturing method, which adopts the mask insulating film 8 as an etching mask for the fuse layer 7 similarly to the second embodiment and involves performing over etching excessively similarly to the first embodiment.

As described above, the present invention is not limited to the above-mentioned embodiments, and various combinations and modifications can be employed without departing from the gist of the present invention.

What is claimed is:

1. A semiconductor device, comprising:
a semiconductor substrate;
a base insulating film formed on the semiconductor substrate;
a fuse element formed on the base insulating film, and comprising a laser irradiation portion having a lengthwise direction and a widthwise direction; and
a protective insulating film covering the fuse element,
the laser irradiation portion having, in the lengthwise direction, chamfers between a bottom surface of the laser irradiation portion and a first side surface of the laser irradiation portion and between the bottom surface and a second side surface of the laser irradiation portion, the bottom surface being in contact with the base insulating film, the first side surface being located at one end of the laser irradiation portion in the widthwise direction, the second side surface being located at another end of the laser irradiation portion in the widthwise direction.

2. The semiconductor device according to claim 1, wherein each of the chamfers is connected to a top surface of the laser irradiation portion.

3. The semiconductor device according to claim 1, wherein each of the chamfers has a rounded surface protruding toward outside of the laser irradiation portion.

4. The semiconductor device according to claim 1, wherein a top surface of the laser irradiation portion is parallel to the bottom surface.

5. The semiconductor device according to claim 2, wherein a top surface of the laser irradiation portion is parallel to the bottom surface.

6. The semiconductor device according to claim 3, wherein a top surface of the laser irradiation portion is parallel to the bottom surface.

7. The semiconductor device according to claim 1 wherein a top surface of the laser irradiation portion comprises a recessed portion having a bottom part being parallel to the bottom surface.

8. The semiconductor device according to claim 2 wherein a top surface of the laser irradiation portion comprises a recessed portion having a bottom part being parallel to the bottom surface.

9. The semiconductor device according to claim 3 wherein a top surface of the laser irradiation portion comprises a recessed portion having a bottom part being parallel to the bottom surface.

10. A method of manufacturing a semiconductor device, comprising:
forming a base insulating film on a semiconductor substrate;
forming a fuse layer on the base insulating film;
forming, after depositing an insulating layer on the fuse layer, an insulating layer mask on a region of the insulating layer in which a fuse element is to be formed;
forming the fuse element, in which a corner portion between a bottom surface of the fuse element and a side surface of the fuse element is chamfered, by dry etching the fuse layer with use of the insulating layer mask as an etching mask; and
forming a protective insulating film on the fuse element.

11. The method of manufacturing a semiconductor device according to claim 10, wherein the forming of the fuse element comprises forming the fuse element, in which the corner portion between the bottom surface and the side surface is chamfered, by etching the fuse layer to expose the base insulating film and by performing overetching under the same condition as a condition of the etching.

12. The method of manufacturing a semiconductor device according to claim 10, wherein the insulating layer mask comprises a photoresist.

13. The method of manufacturing a semiconductor device according to claim 10, wherein the insulating layer mask comprises a silicon oxide film.

14. A method of manufacturing a semiconductor device, comprising:
forming a base insulating film on a semiconductor substrate;
forming an insulating film recessed portion by isotropic etching in a region of the base insulating film in which a fuse element is to be formed;
forming a fuse layer on the base insulating film including the insulating film recessed portion;
forming, after depositing an insulating layer on the fuse layer, an insulating layer mask on a region of the insulating layer in which the fuse element is to be formed;
forming the fuse element, in which a corner portion between a bottom surface and a side surface of the fuse element is chamfered, by dry etching the fuse layer with use of the insulating layer mask as an etching mask; and
forming a protective insulating film on the fuse element.
